(19) United States
(12) Patent Application Publication
(10) Pub. No.: US 2003/0190814 A1
(43) Pub. Date: Oct. 9, 2003

(54) Method of reducing micromasking during plasma etching of a silicon-comprising substrate

(75) Inventors: Ajay Kumar, Sunnyvale, CA (US); Ansul Khan, Sunnyvale, CA (US); Dragan V. Podlesnik, Palo Alto, CA (US); Jeffrey D. Chinn, Foster City, CA (US)

Correspondence Address: APPLIED MATERIALS, INC., 2881 SCOTT BLVD. M/S 2061, SANTA CLARA, CA, 95050, US

(73) Assignee: Applied Materials, Inc., Santa Clara, CA (US)

(21) Appl. No.: 10/155,424

(22) Filed: May 23, 2002

Related U.S. Application Data
(63) Continuation of application No. 09/471,555, filed on Dec. 23, 1999.

(51) Int. Cl. H01L 21/302; H01L 21/461

(52) U.S. Cl. 438/711; 438/709

(57) ABSTRACT

A method for plasma etching substrates having high open area patterns is described. The method is useful in microelectrical mechanical system (MEMS) applications, and in the fabrication of integrated circuits and other electronic devices. The method can be used to etch strict profile control trenches with 89° +/−1° sidewalls on silicon substrates with high open area patterns such as patterns between about 50% and about 90%. The novel method plasma etches high open area substrates using a plasma formed from a gaseous mixture that includes an oxygen source gas, a fluorine source gas and a fluorocarbon source gas. In an alternative embodiment, the fluorocarbon source gas is a passivation gas. In another alternative embodiment, the fluorocarbon source gas consists essentially of a fluorocarbon having fluorine and carbon in a 2:1 ratio. In another particular embodiment, the oxygen source gas is O₂, the fluorine source gas is SF₆ and the fluorocarbon source gas is C₄F₈.

### BACKGROUND OF THE INVENTION

1. Field of the Invention

The present invention relates to plasma etch processes and more specifically to plasma etch processes conducted on silicon substrates and films with mask patterns having large open areas.

2. Description of Related Art

Typical design parameters for electronic device applications such as DRAM memory, deep trench isolation, power devices, and high frequency silicon on insulator devices are less than about 10 to 15 percent open area. These devices are commonly formed on silicon substrates or have layers that include silicon. Open area is defined as a ratio between the area of silicon to be etched to the total area of the silicon substrate surface. Conventional HBr, SF₆, O₂ plasma etch chemistries are suited for low open area (i.e., less than about 15% open area) etch patterns. As open area percentage increases, the availability of additional silicon from the substrate surface creates problems.

One problem affects the chemical balance of the plasma. In fluorine based etch chemistries, there is a constant competition between fluorine radicals that etch and oxygen radicals that passivate the silicon. Increasing the percentage of open area influences the balance between etching and passivation. Another problem is micro masking. As the percentage of open area increases, the likelihood also increases that sputtered mask material or etch reaction byproducts may redeposit on the substrate surface and act as a micro mask. Generally, conventional plasma etch processes typically have a directional etch component. As a result of the directional etch component [symbol] the micro mask produces spikes. A spike consists of a silicon body with a thin passivating siliconoxyfluoride skin. When viewed by an observer, light with a wavelength less than the length of the spikes will be reflected and caught between spikes thereby making the area with spikes appear dark. Spike formation as a result of directional etching around the micromask is commonly referred to as ‘black silicon’ because of this observed darkening of the silicon surface. The redeposition of mask material and etch byproducts that result in micromasking and subsequent spike formation is not acceptable because areas which should stay clean become contaminated thereby, reducing the useful area of the substrate.

The silicon spikes can be removed in conventional HBr—SF₆ based chemistry by increasing the SF₆ flow. SF₆ dissociates in the plasma forming F* (i.e., fluorine radicals) for an isotropic etch component that can be used to remove silicon spikes. While the isotropic etch component provided by the additional fluorine removes the silicon spikes, the isotropic nature of the additional fluorine can lead to undesired results, for example, diminished profile control, undercutting of the mask layer and loss of sidewall passivation. In addition to these undesired results, it is believed HBr contributes to silicon spike formation when open area percentage increases above about 15 percent.

A plasma process for etching silicon based on SF₆, O₂ and CHF₃ chemistry has been proposed in an article entitled “The Black Silicon Method” by Henri Jansen, Meint de Boer, Bert Otter and Miko Elvenspock, Journal of Micromachining and Microengineering 5, 115-120, (1995). While the moderately reentrant sidewall profiles obtained by Jansen et al. may prove useful in large-scale, low precision microelectromechanical systems (MEMS) applications, these profiles are not suited to more precise MEMS applications or electronic device fabrication where vertical sidewalls (i.e., sidewalls of about 89° +/−1°) are required. Additionally, an SF₆—O₂ based plasma using CHF₃ as a passivant is likely to have a high a degree of byproduct formation. CₓH_{y}O_{z} deposits will likely form because of the deposition reaction between carbon, hydrogen and oxygen atoms available from this plasma. The CₓH_{y}O_{z} deposits can increase the probability of redeposition and micromasking thereby, potentially increasing the likelihood of silicon spike formation. The CₓH_{y}O_{z} deposits may also form deposits on chamber walls and other components thereby increasing post etch cleaning times and decreasing throughput.

Another proposed plasma process for etching silicon is the SF₆—C₄F₈ pulsed process described in an article entitled “Deep Silicon Etching in Inductively Coupled Plasma Reactor for MEMS” by J. Kiihamaki and S. Franssila, Physia. Scripta. Vol. T79, 250-254, (1999). In this process, an SF₆ based plasma is pulsed providing fluorine radicals that form an isotropic silicon etch profile. The SF₆ is shut-off and then a C₄F₈ plasma is pulsed resulting in a polymer deposition. The isotropic etch polymer deposition sequence of this process results in a rippled side wall profile. The rippled side wall profiles produced by pulsed etch-deposition methods are not suited to applications requiring smooth sidewalls such as high precision MEMS fabrication and electronic device fabrication that require smooth, vertical sidewalls.

Thus, what is needed is a plasma etch chemistry capable of etching vertical, smooth sidewall profiles on high percentage open area silicon structures and layers without forming silicon spikes.

### SUMMARY OF THE INVENTION

Embodiments of the present invention relate to a plasma etching method that includes the steps of loading a silicon substrate having a high percentage open area pattern formed thereon; forming a plasma from a gaseous mixture including an oxygen containing gas, a fluorine containing gas and a fluorocarbon containing gas; and etching a portion of the silicon substrate with the plasma.

### BRIEF DESCRIPTION OF DRAWINGS

The teachings of the present invention can be readily understood by considering the following detailed description in conjunction with the accompanying drawings, in which:

FIGS. 1A, 1B, 1C, 1D, 1E and 1F depict various high open area patterns;

FIG. 2 is a schematic, cross section view of a semiconductor process chamber in which embodiments of the inventive method of FIG. 3 can be performed; and

FIG. 3 is a block diagram depicting an embodiment of the inventive method of etching silicon with an oxygen, fluorine, and fluorocarbon plasma.

To facilitate understanding, identical reference numbers are used, where possible, to designate identical elements that are common to the figures.

### DETAILED DESCRIPTION OF THE PREFERRED EMBODIMENTS

Embodiments of the present invention provide a fluorine, oxygen, and fluorocarbon based plasma etch method capable of anisotropically etching silicon in high percentage open area etch patterns without forming silicon spikes (i.e., black silicon). Generally the total surface area of the silicon substrate to be etched includes etched area and masked area. The percentage of open area refers to the ratio of the etched area to the total area of the silicon substrate. Design parameters for some devices, such as for example, DRAM memory, deep trench isolation and high frequency silicon on insulator devices, maintain open area percentage below about 20 percent and in most cases less than 15 percent.

In a silicon etch context, high open area percentages (i.e., open area percentages above 50 percent) result in an increasing availability of silicon and an increasing likelihood of silicon spike or black silicon formation. As the percentage of open area increases, the likelihood also increases that sputtered mask material or etch reaction byproducts may redeposit on the substrate surface and act as a micro mask. The directional etch component needed for vertical sidewalls and anisotropic etching of desired features also results in directional etching around the micromask. As a result of the directional etch component, the micro mask produces spikes. A spike consists of a silicon body with a thin passivating siliconoxyfluoride skin. When viewed by an observer, light with a wavelength less than the length of the spikes will be reflected and caught between spikes thereby making the area with spikes appear dark. Spike formation as a result of directional etching around the micromask is commonly referred to as ‘black silicon’ because of this observed darkening of the silicon surface. The redeposition of mask material and etch byproducts that result in micromasking and subsequent spike formation is not acceptable because areas which should stay clean become contaminated reducing the useful area of the substrate or structure. While the formation of black silicon is more pronounced at higher open area percentages, black silicon formation has been observed in patterns having 25 percent open area.

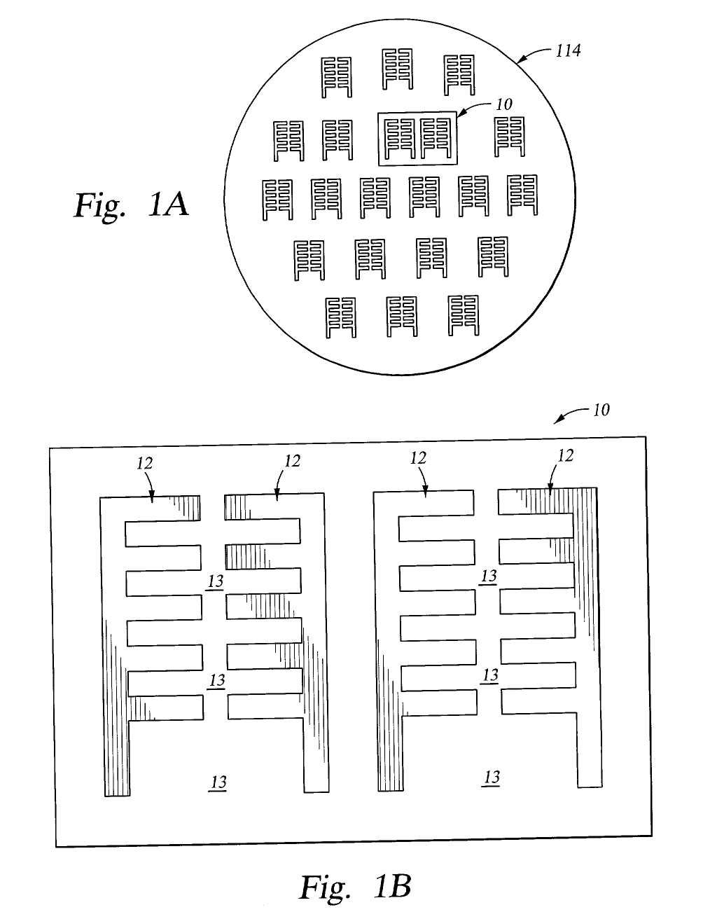

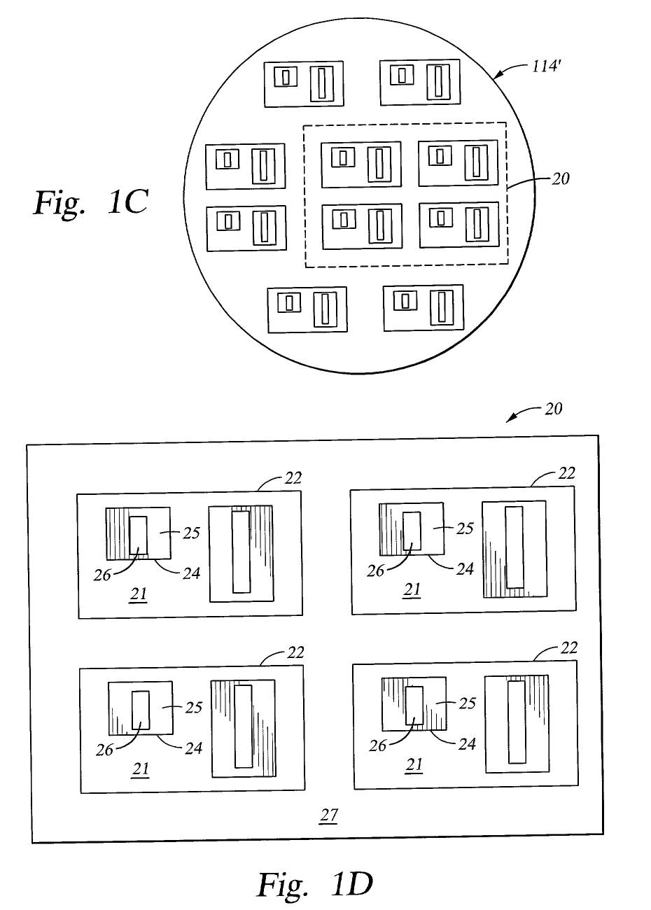

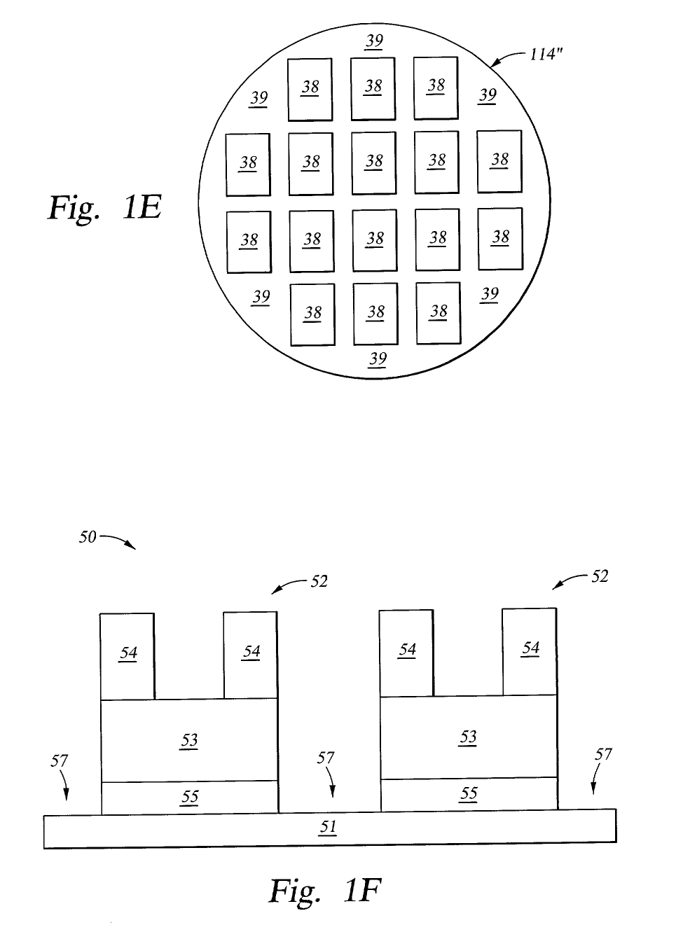

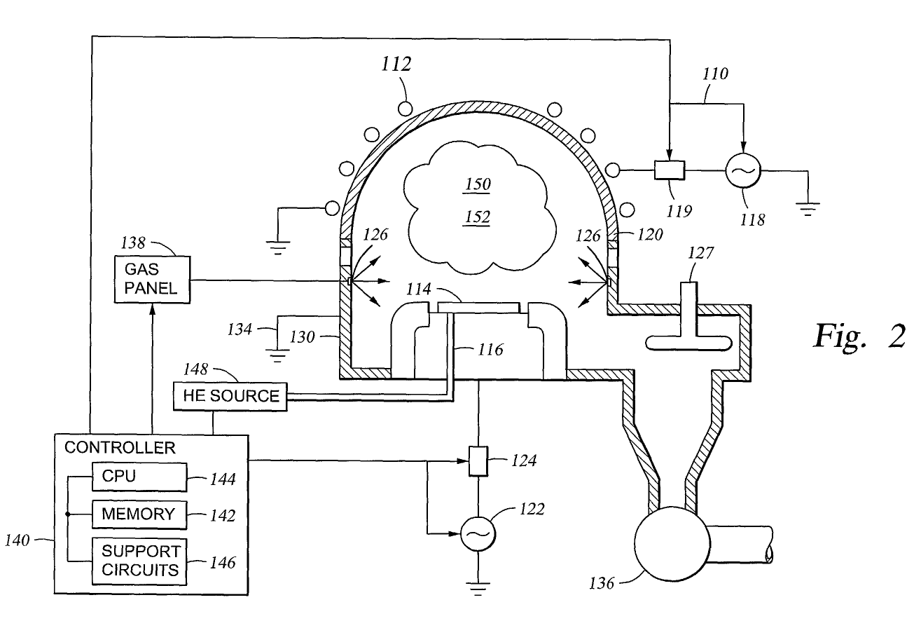

High percentage open area patterns can exist in microelectrical mechanical system (MEMS) applications as illustrated by FIGS. 1A and 1B. FIG. 1A represents a silicon substrate 114 patterned for a MEMS application. FIG. 1B illustrates an enlarged portion 10 of the patterned surface of substrate 114. Enlarged portion 10 illustrates several masking patterns 12 that are repeated across the surface of the wafer 114. FIG. 1B illustrates how open area 13 exists between and around each masking pattern 12. In typical MEMS application, the structures formed by masking pattern 12 are generally 10 to 100 microns long and typically tens of microns wide. Open area 13 varies greatly depending upon the structure type being fabricated. Generally, several microns of open area separate the individual masking patterns 12 in order to provide sufficient spacing between the masking patterns 12 for proper fabrication.

High percentage open area patterns can also exist in electronic and integrated circuit fabrication as illustrated by FIGS. 1C and 1D. FIG. 1C represents a silicon substrate 114 patterned for an electronic device application. FIG. 1D illustrates an enlarged view 20 of a portion of the representative device pattern. Enlarged view 20 includes several individual device patterns 22. Each device pattern 22 includes several masking areas 24 that each include mask areas 25 and open areas 26. Open area 21 exists in the remainder of each individual device pattern 22 not covered by a mask area 25. Thus, the open area of each individual device pattern 22 includes open areas 26 and 21. The overall open area of the silicon wafer 114′ includes not only the open area of each individual device pattern 22 but also the open area 27 that exists between and around each individual device pattern 22. In a representative device pattern structure, such as a silicon on insulator device, spaces within the structures are about 1 to 2 microns wide with trenches of between about 20 to about 40 microns deep with a spacing between individual devices of between about 2 to about 20 microns.

High percentage open area patterns can also exist on a macro or overall substrate level as illustrated by FIG. 1E. FIG. 1E represents the overall view of a silicon substrate 114″ having numerous individual etch patterns 38. Individual etch patterns 35 could be, for example, MEMS etch patterns such as masking pattern 12 of FIG. 1B or electronic device etch patterns such as individual device etch patterns 22 of FIG. 1D or a combination of both MEMS and electronic devices. The overall arrangement of the individual etch patterns 38 results in a high percentage open area layout for the silicon substrate 114″. The open area 39 makes up the remainder of the surface area of silicon substrate 114″ not covered by the individual etch patterns 38. In this context, regardless of the open area percentage of any individual etch pattern 38, the overall open area percentage for silicon substrate 114″ is large. Thus, high percentage open area can be present on the silicon substrate 114″ even in the case where the open area percentage of each individual etch pattern 38 is low or less than about 15 percent.

The representative embodiments of FIGS. 1A through 1E illustrate silicon etch mask patterns for both MEMS and IC fabrication where the percentage of open area is greater than 20 percent and preferably more than 50 percent of the silicon substrate being etched. High percentage open area etch patterns may also exist when etching a silicon layer that is part of a multi-layer stack. FIG. 1F illustrates a representative silicon on insulator pattern 50. Insulator pattern 50 includes several multi-layer structures 52 formed on a silicon substrate [symbol] 57. Multi-layer structure 52 represents a typical silicon etch layer stack were oxide layer 55 is used as a stop etch layer. An etch process for such a layered arrangement is commonly referred to in the art as silicon etch-stop on oxide. In multi-layer structure 52, a poly silicon layer 53 is formed on top of an oxide stop layer 55 and is patterned by a mask layer 54. During an etch process, polysilicon layer 53, mask layer 54 and exposed areas of silicon substrate 57 are etched. As with individual device pattern 22, the open area of insulator pattern 50 includes not only the open area of each individual patterned area (i.e., the exposed poly silicon layer 53 in each multi-layer structure 52) but also the exposed silicon substrate 57 between and adjacent to each of the structures 52. It is to be appreciated that the silicon layer could be formed from amorphous silicon, polysilicon, crystalline silicon or combinations thereof. Embodiments of the plasma etching method of the present invention are useful in plasma etching silicon substrates and layers having mask patterns with high open area percentages up to 80 percent open area and even as high as 90 percent open area.

It is to be appreciated that embodiments of the present invention are useful in etching devices and structures that are combinations of integrated circuits, electronic devices and microelectrical mechanical devices (MEMS) that are formed on the same silicon substrate. Because of the complex interrelation between the individual devices in a combined application, the complexity in fabricating these mixed component applications increases, thereby requiring increased etch profile control in addition to preventing the formation of silicon spikes. One example of a mixed component application is an optical device that converts optical signals into analog or digital signals. Such a device requires integrated circuit fabrication as well as optical or photodiode fabrication. Devices of this type are useful in a number of computer applications. For example, a diode could be formed on a P-I-N structure to provide CMOS pixel control circuitry for controlling a computer display. One representative multi-layer structure useful in such optical applications is a PIN type device. The bottom electrode of the device is connected to CMOS devices by contact vias. On top of the bottom electrode a PIN structure is formed (i.e., a layer of intrinsic or undoped silicon formed between a layer of p-doped amorphous silicon and a layer of n-doped amorphous silicon). A layer of translucent material such as Indium Tin Oxide (ITO) or other suitable photodiode film is formed on top of the PIN structure. Embodiments of the present invention could be used to etch the various layers of the described and other optical devices.

Embodiments of the present invention etch silicon that is part of a high percentage open area etch pattern with a plasma formed from a gaseous mixture that includes an oxygen gas source, a fluorine gas source and a fluorocarbon gas source. The plasma etch process of the present invention provides an anisotropic etch with nearly vertical, smooth sidewalls without undercutting the mask layer. In this context, nearly vertical sidewalls refer to sidewalls that are 89° +/−1° relative to the etching plane of the substrate. The plasma etch process of the present invention can be reduced to practice in a number of etching systems. One such system is a Decoupled Plasma Source (DPS) Centura etch system available from Applied Materials, Inc., of Santa Clara, Calif.

FIG. 2 depicts a schematic diagram of the DPS etch process chamber 110, that comprises an inductive coil antenna segment 112, positioned exterior to a dielectric, dome [symbol] capped ceiling 120 (referred hereinafter [symbol] dome 120). The antenna segment 112 is coupled to a radio-frequency (RF) source 118 that is generally capable of producing a 200 W-3000 W RF signal having a tunable frequency of about 12.56 MHz. The RF source 118 is coupled to the antenna segment 112 via a matching network 119. The process chamber 110 also includes a substrate support pedestal (cathode) 116 that is coupled to a second RF source 122 capable of producing a 10W-200 W RF signal having a frequency of approximately 400 kHz. The second RF source 122 is coupled to the substrate support pedestal 116 through a matching network 124. Hereinafter, the first and second RF sources 118, 122 will be referred to, respectively, as RF source generator 118 and RF bias generator 122, respectively. Chamber 110 also contains a conductive chamber wall 130 that is coupled to an electrical ground 134. A controller 140 comprising a central processing unit (CPU) 144, a memory 142, and support circuits 146 for the CPU 144 is coupled to the various components of the DPS process chamber 110 to facilitate control of the etch process.

In operation, a semiconductor substrate 114 is placed on the substrate support pedestal 116 and gaseous components are supplied from a gas panel 138 to the process chamber 110 through inlets 126 to form a gaseous mixture 150. The gaseous mixture 150 is ignited into a plasma 152 in the process chamber 110 by applying RF power from the RF source and bias generators 118 and 122, respectively, to the antenna segment 112 and the substrate support pedestal 116. The pressure within the interior of the process chamber 110 is controlled using a throttle valve 127 situated between the chamber 110 and a vacuum pump 136. The temperature at the surface of the chamber wall 130 is controlled using liquid containing [symbol] cond (not shown) that are located within the walls 130 of the chamber 110. For example, the walls 130 can be maintained at about 65 degrees Celsius during processing.

The temperature of the substrate 114 is controlled by stabilizing the temperature of the support pedestal 116 and providing He gas from a He source 148 to channels formed between the back of the substrate 114 and grooves (not shown) on the surface of support pedestal 116. The He facilitates heat transfer between the substrate 114 and the support pedestal 116. During the etch process, the substrate 114 is gradually heated by the plasma 150 to a steady state temperature. Typically, substrate 114 is maintained in a temperature range of between about −40 to about 60 degrees Celsius with a preferred operating range of about 15 to about 20 degrees Celsius.

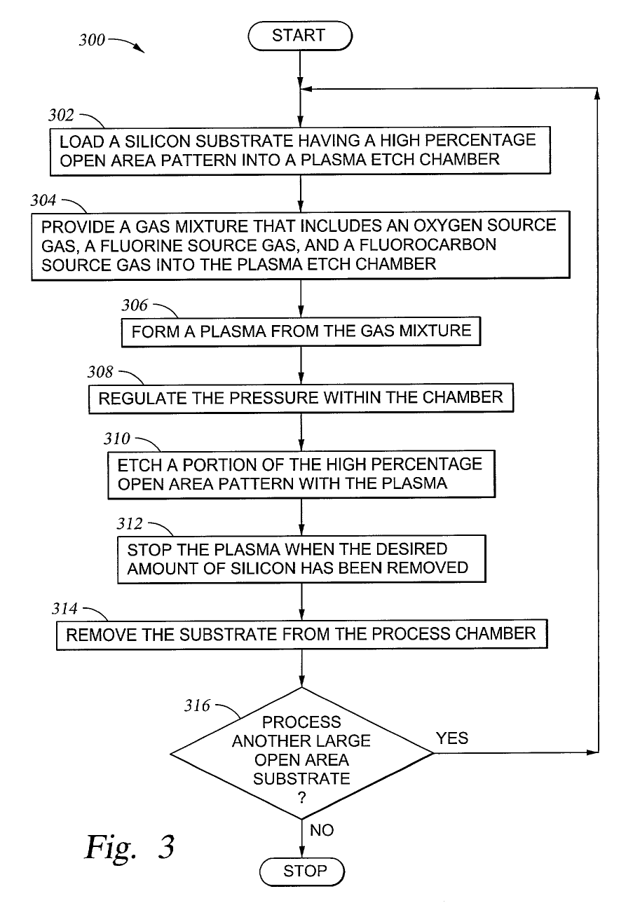

To facilitate control of the chamber as described above, the CPU 144 may be one of any form of general purpose computer processors that can be used in an industrial setting for controlling the various chamber components and even other processors in a processing system where computer controlled chamber components are utilized. The memory 142 is coupled to the CPU 144. The memory 142, or computer readable medium, may be one or more of readily available memory such as random access memory (RAM), read only memory (ROM), floppy disk drive, hard disk, or any other form of digital storage, local or remote. The support circuits 146 are coupled to the CPU 144 for supporting the processor in a conventional manner. Support circuits 146 include cache, power supplies, clock circuits, input/output circuitry and subsystems, and the like. An etch process, such as the etch process 300 of FIG. 3, is generally stored in the memory 142, typically as a software routine. The software routine may also be [symbol] ed and/or executed by a second CPU (not shown) that is remotely located from the hardware being controlled by the CPU 144.

The software routine executes the etch process, such as process 300 of FIG. 3, to operate the chamber 110 to perform the steps of the process. When executed by the CPU 144, the software routine transforms the general purpose computer into a specific process computer (controller) 140 that controls the chamber operation to perform a process such as etch process 300. Although the process of the present invention is discussed as being implemented as a software routine, some or all of the method steps that are discussed herein may be performed in hardware as well as by the software controller. As such, the invention may be implemented in software and executed by a computer system, in hardware as an application-specific integrated circuit or other type of hardware implementation, or in a combination of software and hardware.

The plasma etch method of the present invention can be better appreciated by turning to process 300 of FIG. 3. According to step 302, the first step in the present invention is to load a substrate having a high percentage open area pattern into a plasma etch chamber. A high percentage open area pattern refers to the high percentage open area patterns illustrated in FIGS. 1A through 1F. A high percentage open area structure could be any pattern arrangement for MEMS or electronic device fabrication with open area percentages greater than about 20 percent. In a specific embodiment, the open area percentage is greater than 50 percent. In another specific embodiment, the percentage of open area is about 80 percent. Referring to FIG. 2, step 302 represents placing substrate 114 onto the substrate support 116 within chamber 110.

Next, according to step 304, provide a gas mixture that includes an oxygen source gas, a fluorine source gas and a fluorocarbon source gas into the plasma etch chamber. In order to provide more precise control of the amount of oxygen, fluorine and fluorocarbon in the gaseous mixture, three separate gas sources are provided, one each for an oxygen source, a fluorine source and a fluorocarbon source. Oxygen can be supplied from any of a number of compounds such as, for example, oxygen or oxygen diluted in an inert gas. A diluted oxygen source gas could be provided in a suitable diluted ratio, such as for example, a ratio of about 70% inert gas and 30% O₂. One representative inert gas is helium. A preferred oxygen source gas is O₂. Fluorine acts as the primary etchant and can be provided from any of a number of multi-fluorine atom compounds such as, for example, CF₄, NF₃ and SF₆. A preferred fluorine source gas is SF₆. Suitable fluorocarbon source gases contain fluorine and carbon in a ratio of two fluorine atoms for each carbon atom. The fluorocarbon source gas is also selected for its ability to provide (CF₂)ₙ type polymers (i.e., Teflon) or other polymer precursor atoms to promote sidewall passivation. As such, the fluorocarbon source also acts as a passivation gas. Preferred fluorocarbon source gases also provide additional fluorine to promote vertical sidewall profiles and prevent black silicon formation. Suitable fluorocarbon source gases include, for example, C₂F₄, C₃F₆ and C₄F₈. A preferred fluorocarbon source gas is C₄F₈.

The next step of the present invention, as set forth in step 306, is form a plasma from the gas mixture that includes oxygen, fluorine and a fluorocarbon (step 304). A plasma is formed, for example in the DPS chamber 110 of FIG. 2, by applying RF energy from the source 118 and bias 122 RF generators. The source RF generator 118 provides inductive power into the plasma for the formation of or control of the plasma density and the bias RF generator 122 provides bombardment energy and directionality of ions to the substrate 114. In a specific embodiment, the source power level is about 700 W and the bias power level is about 25 W.

Next, according to step 308, regulate the pressure in the chamber. Referring to FIG. 2 in chamber 110, pressure within chamber 110 is regulated by throttle valve 127. Generally, pressure is maintained in a range of less than 100 mT during the plasma etch. In a particular embodiment, for example, pressure within chamber 110 could be about 20 mT. It is to be appreciated that the steps 304, 306 and 308 are represented and described serially for clarity. One of ordinary skill will appreciate that the steps could be performed in a different order or nearly simultaneously.

The next step of the present invention, as set forth in step 310, is etch a portion of the high percentage open area pattern with the plasma. In the fluorine, oxygen, fluorocarbon plasma of the present invention, it is believed each source gas has a specific function in the silicon etch process. It is believed that the fluorine source gas produces F* (i.e., fluorine radicals) for the chemical etching of the silicon by forming volatile SiF₄. It is believed that the oxygen source creates O* (i.e., oxygen radicals) to passivate the silicon surface with SiOₓF_{y} and that the fluorocarbon source provides CₓF_{y} precursors for sidewall passivation. Additionally, it is believed XFₓ⁺ ions, formed from either or both of the fluorine source gas and a fluorocarbon source gas, etch the SiOₓF_{y} layer. For example, C₄F₈ may form CFₓ⁺ that etches in this plasma by forming volatile COₓF_{y} and SF₆ may form SFₓ⁺ that ecthes in this plasma by forming volatile [symbol] _{y}. Embodiments of the present invention provide each of the source gases in a ratio that forms an anisotropic silicon etching plasma which, advantageously, results in smooth, vertical sidewall profiles and no black silicon formation.

The silicon etch performed during step 310 is maintained for a suitable period of time and then extinguished (step 312). The plasma is maintained for a period of time suited to etching the desired features. Etch time will vary based on the ratio of the gases provided, and features present on the substrate, as well as the relative etch rates of the silicon and the masking layer. Embodiments of the present invention provide anisotropic (e.g., vertical sidewalls of about 89° +/−1°) etch profiles at etch rates greater than 2 microns per minute.

Finally at step 314, remove the substrate from the process chamber.

If more substrates are to be etched according to the present method, the response at step 316 is ‘YES’. In that case, another substrate is loaded according to step 302. If no additional substrates are to be processed, the response at step 316 is ‘NO’ and the processing sequence according to the inventive method ends.

In one illustrative embodiment, the etch process 300 is reduced to practice by:

loading a substrate having a high percentage open area pattern into a plasma etch chamber (step 302);

providing a gas mixture of approximately 40 sccm SF₆, approximately 60 sccm O₂ and approximately 20 C₄F₈ into the plasma etch chamber (step 304);

forming a plasma from the gas mixture by supplying source RF power of between about 500W to about 1000W and bias RF power of between about 10W to 200W (step 306); and

regulating the chamber pressure to below about 100 mT (step 308).

In another specific embodiment, the advantageous results of the present invention are obtained by providing a gas mixture (step 304) with a flow rate of SF₆ that is about twice the C₄F₈ flow rate and a flow rate of O₂ that is about three times the flow rate of C₄F₈. In another specific embodiment, the flow rate of C₄F₈ is about 20 sccm.

In an alternative embodiment, the advantageous results of the present invention are obtained by providing a gas mixture (step 304) with a total gas flow into the chamber of about one-third fluorine containing gas, about one-half oxygen containing gas and about one-sixth fluorocarbon containing gas. In a specific embodiment, a fluorine containing gas is SF₆, the oxygen containing gas is O₂ and the fluorocarbon containing gas is C₄F₈.

Although present invention has been disclosed to illustratively using a DPS process chamber, the invention may be practiced in other etching equipment where the processing parameters may be adjusted to achieve acceptable etch characteristics. For example, an RF bias generator operating at another frequency may be used to provide a comparable amount of RF power to the support pedestal. For example, an RF bias generator providing 60W at about 13 MHz is comparable to an RF bias generator providing 25W at about 400 kHz. These and other modifications will occur to those skilled in the arts utilizing the teachings disclosed herein and without departing from the spirit of the present invention.

We claim:

1. A plasma etching method comprising:
loading a substrate having a high percentage open area pattern formed thereon;
forming a plasma from a gaseous mixture including an oxygen containing gas, a fluorine containing gas and a fluorocarbon containing gas; and
etching a portion of the substrate with the plasma.

2. A method according to claim 1 wherein the high open area pattern is a MEMS structure.

3. A method according to claim 1 wherein said high percentage open area pattern is an electronic device structure.

4. A method according to claim 1 wherein said high percentage open area pattern comprises an integrated circuit pattern and a MEMS pattern.

5. A method according to claim 1 wherein said high percentage open area pattern is an optical device.

6. A method according to claim 1 wherein the high open area pattern results from the overall pattern of the substrate.

7. A method according to claim 1 wherein said fluorine containing gas is SF₆ and said fluorocarbon containing gas is C₄F₈.

8. A method according to claim 1 wherein the total flow of said gaseous mixture is about one-third fluorine containing gas, about one-half oxygen containing gas and about one-sixth fluorocarbon containing gas.

9. A method according to claim 1 wherein the flow rate of said fluorine containing gas is about twice the flow rate of the fluorocarbon containing gas.

10. A method according to claim 1 wherein the flow rate [symbol] of said oxygen containing gas is about three times the flow rate of the fluorocarbon containing gas.

11. A method according to claim 1 wherein the flow rate of said fluorocarbon containing gas is about 15 percent of the total gas flow of said gaseous mixture.

12. A method of plasma etching a substrate with high open area patterns, comprising:
loading a substrate having a high open area pattern formed thereon into a processing chamber;
forming a plasma from a gaseous mixture comprising an oxygen source gas, a fluorine source gas, and a passivation gas; and
etching a smooth, sidewall structure in a portion of the substrate with said plasma formed from said gaseous mixture.

13. A method according to claim 12 wherein said passivation gas consists essentially of carbon and fluorine.

14. A method according to claim 13 layer in the ratio of fluorine to carbon is about 2:1.

15. A method according to claim 12 wherein about 50 percent of the total gas flow of said gaseous mixture is an oxygen source gas.

16. A method according to claim 12 wherein the flow rate of the oxygen source gas is about three times the flow rate of the passivation gas and a flow rate of the fluorine source gas is about twice the flow rate of the passivation gas.

17. A method according to claim 16 wherein the oxygen source gas is O₂, the fluorine source gas is SF₆, and a passivation gas is C₄F₈.

18. A method according to claim 12 wherein said structure has at least 89° sidewalls.

19. A method of plasma etching a trench in silicon, comprising:
loading a silicon substrate having a high open area pattern formed thereon into a plasma processing reactor;
forming a plasma from a mixture consisting essentially of an oxygen source gas, a fluorine source gas and a fluorocarbon source gas;
etching a trench in said silicon substrate with said plasma, said trench having vertical smooth side walls.

20. A method according to claim 19 wherein said fluorocarbon source gas is C₄F₈.

21. An apparatus for etching silicon in a plasma etch chamber, comprising:
a gas panel coupled to said plasma etch chamber;
an antenna proximate to said plasma etch chamber;
a first power supply coupled to said antenna;
a substrate support disposed within said plasma etch chamber;
a second power supply coupled to said substrate support; and
a controller, coupled to said antenna and said gas panel, said controller containing a computer readable storage medium having program code embodied therein, said program code for controlling the apparatus in accordance with the following:
(a) loading into the plasma etch chamber a silicon substrate having a high percentage open area etch pattern formed thereon;
(b) flowing from the gas panel into the plasma etch chamber a gaseous mixture of an oxygen source gas, a fluorine source gas and a fluorocarbon source gas;
(c) controlling said first power supply to provide energy to said antenna and said second power supply to provide energy to said substrate support to form a plasma from said gaseous mixture; and
(d) etching a portion of the silicon substrate with the plasma formed from said gaseous mixture.

22. A method according to claim 21 wherein said gaseous mixture consists essentially of a fluorine source gas, an oxygen source gas and C₄F₈.

23. A method according to claim 22 wherein said oxygen source gas is O₂ and said fluorine source gas is SF₆.

24. A method according to claim 23 wherein the controller controls the O₂ flow rate to be about three times the C₄F₈ flow rate and the SF₆ flow rate to be about twice the C₄F₈ flow rate.
